(19) United States
(12) Patent Application Publication
(10) Pub. No.: US 2010/0032813 A1
(43) Pub. Date: Feb. 11, 2010

(54) IC FORMED WITH DENSIFIED CHEMICAL OXIDE LAYER

(75) Inventors: Deborah J. Riley, Murphy, TX (US); Haowen Bu, Plano, TX (US); Brian Edward Hornung, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/538,280

(22) Filed: Aug. 10, 2009

Related U.S. Application Data
(60) Provisional application No. 61/087,230, filed on Aug. 8, 2008.

(51) Int. Cl. H01L 23/29; H01L 21/31

(52) U.S. Cl. 257/632; 438/758; 257/E23.118; 257/E21.24

(57) ABSTRACT

A semiconductor device, such as an integrated circuit, has an oxide chemically grown on a silicon surface, and densified by annealing at, e.g., 950° C. for 4 to 5 seconds in an N₂ ambient, or at an equivalent thermal profile in a similarly non-oxidizing ambient. The densified chemical oxide has an etch rate the same as that of thermally grown silicon dioxide in common etchants used in IC fabrication.

This application is a non-provisional of Application No. 61/087,230 filed Aug. 8, 2009, the entirety of which is incorporated herein by reference.

### BACKGROUND

This invention relates in general to the formation of semiconductor devices, such as integrated circuits; and, more particularly, to the formation of such devices including a chemical oxide layer for protection during exposure to acidic or alkaline solutions. Background for this application also appears in U.S. Pat. No. 7,384,869, the entirety of which is incorporated herein by reference.

It is common to use silicon nitride for a hardmask material during fabrication of integrated circuits (ICs) built on silicon substrates. During oxidizing processes such as thermal oxidation of a polysilicon gate, the surface of the silicon nitride hardmask may become oxidized. Removal of the silicon nitride hardmask using phosphoric acid then becomes problematic because the oxidized surface significantly slows the etch rate of the silicon nitride and degrades the uniformity of the silicon nitride removal. Removing the oxidized surface on the silicon nitride by dilute or buffered hydrofluoric acid also removes beneficial oxide layers on the surface of the IC which protect silicon regions from etching during the subsequent phosphoric acid process. N-type silicon particularly exhibits a high etch rate in phosphoric acid.

### SUMMARY

The invention provides a method of forming a semiconductor device including a chemical oxide layer that protects a silicon surface from etching during exposure to an acidic or alkaline solution.

In a described embodiment, a densified chemical oxide is formed by annealing a chemical oxide layer in a non-oxidizing ambient, to decrease an etch rate of the chemical oxide in an acidic or alkaline solution to be substantially equivalent to that of thermally grown silicon dioxide. The anneal operation is preferably performed in a rapid thermal processing tool, to minimize diffusion of dopants in the semiconductor device.

The method may be integrated into a fabrication sequence of a semiconductor device such as an integrated circuit with minimal added cost or complexity.

### BRIEF DESCRIPTION OF THE DRAWINGS

FIGS. 1A-1F are cross-sectional views of a semiconductor device, depicting formation of a chemical oxide layer, anneal of the chemical oxide layer to form a densified chemical oxide layer, and subsequent exposure to phosphoric acid during a silicon nitride removal process, according to an example embodiment of principles of the invention.

FIGS. 2A-2E are cross-sectional views of a semiconductor device, depicting formation of a chemical oxide layer, anneal of the chemical oxide layer, and subsequent exposure to alkaline photoresist developer during a photolithographic rework process, according to another example embodiment of the invention.

### DETAILED DESCRIPTION OF EXAMPLE EMBODIMENTS

In an example implementation, a densified chemical oxide is formed on a silicon surface of a semiconductor device in the for of an integrated circuit (IC), to protect the silicon from etching during exposure to an acidic or alkaline solution, as for example during a silicon nitride removal process using phosphoric acid, or a photolithographic rework process using alkaline developer. The illustrative method uses an anneal operation to densify the chemical oxide, so as to decrease an etch rate of the chemical oxide in the acidic or alkaline solution, as, for example, to decrease an etch rate in phosphoric acid to less than 1 percent of a silicon nitride etch rate in the same phosphoric acid. The anneal operation is preferably performed in a rapid thermal processing tool, so that the IC undergoes a thermal profiling which causes dopants in the silicon to diffuse less than 3 nanometers (root-mean-square).

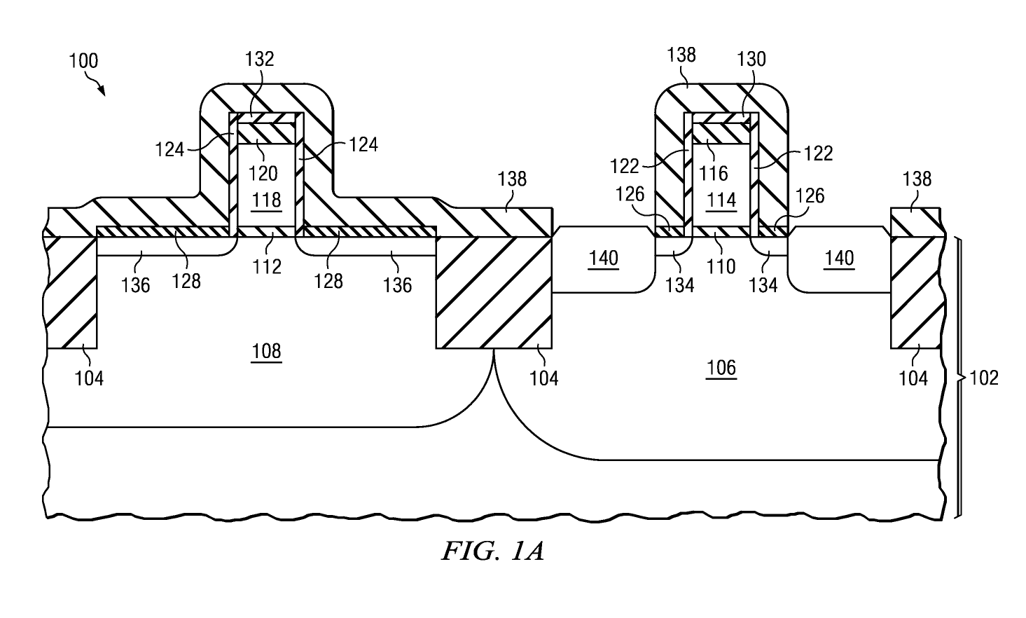

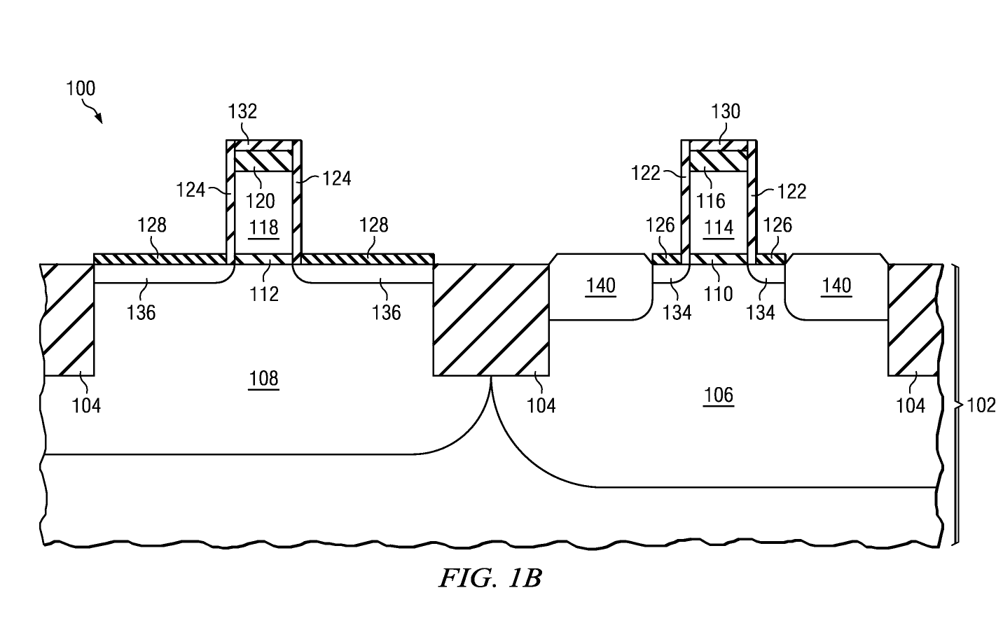

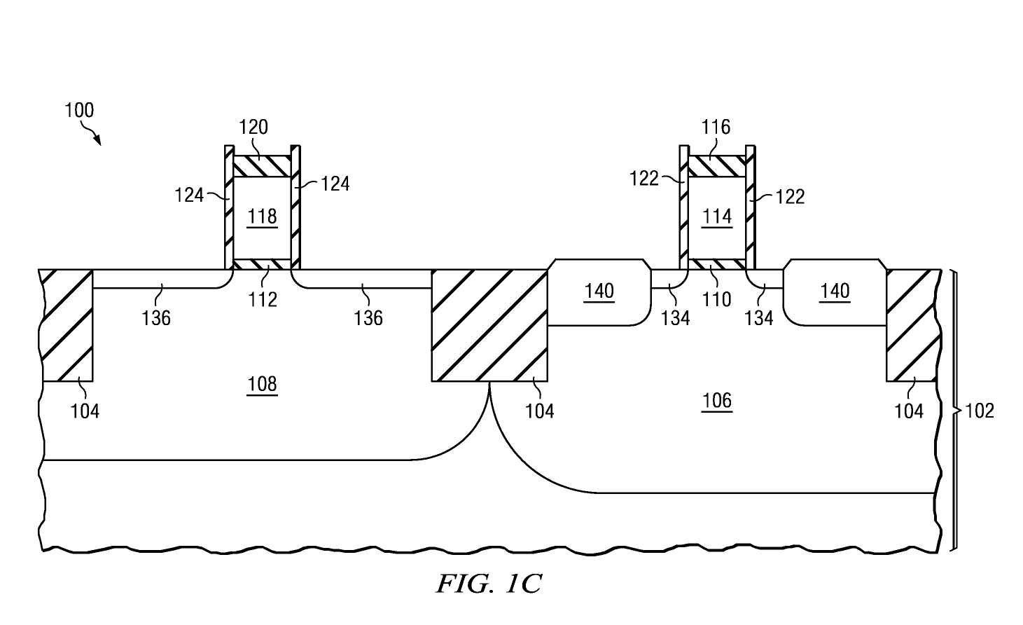

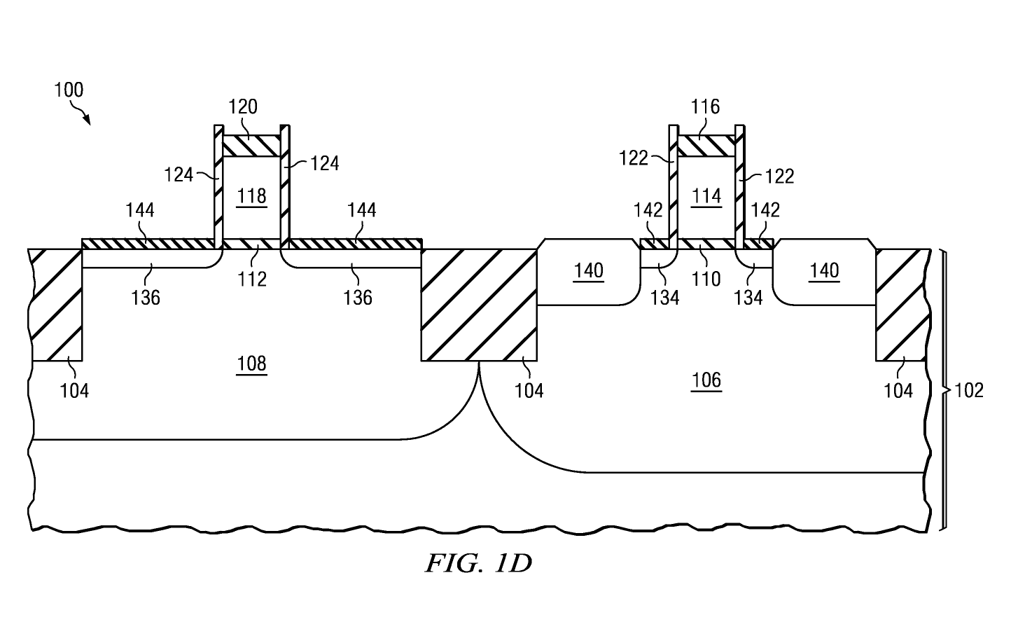

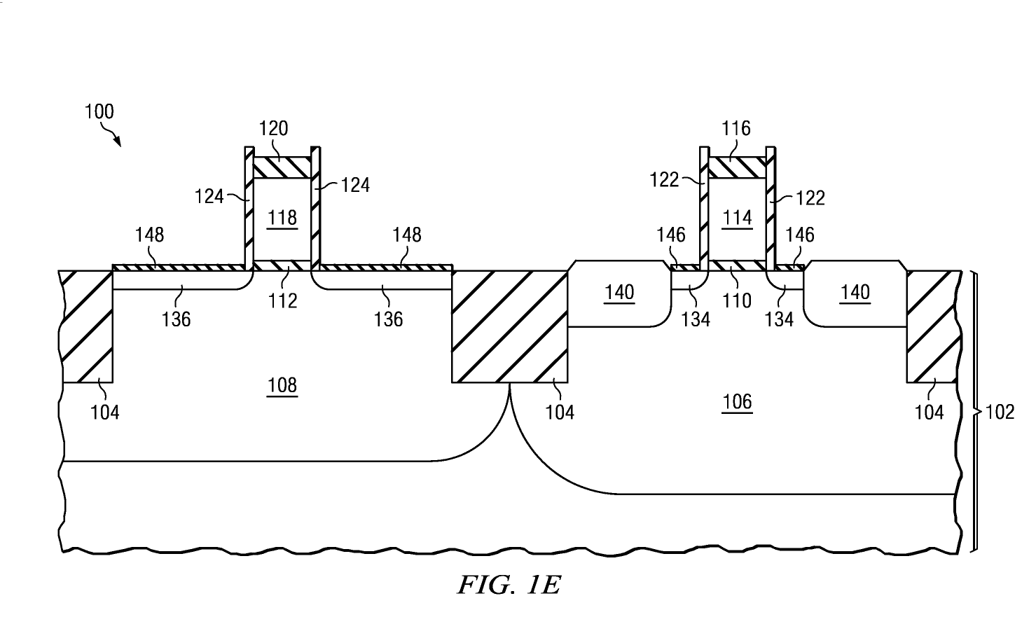

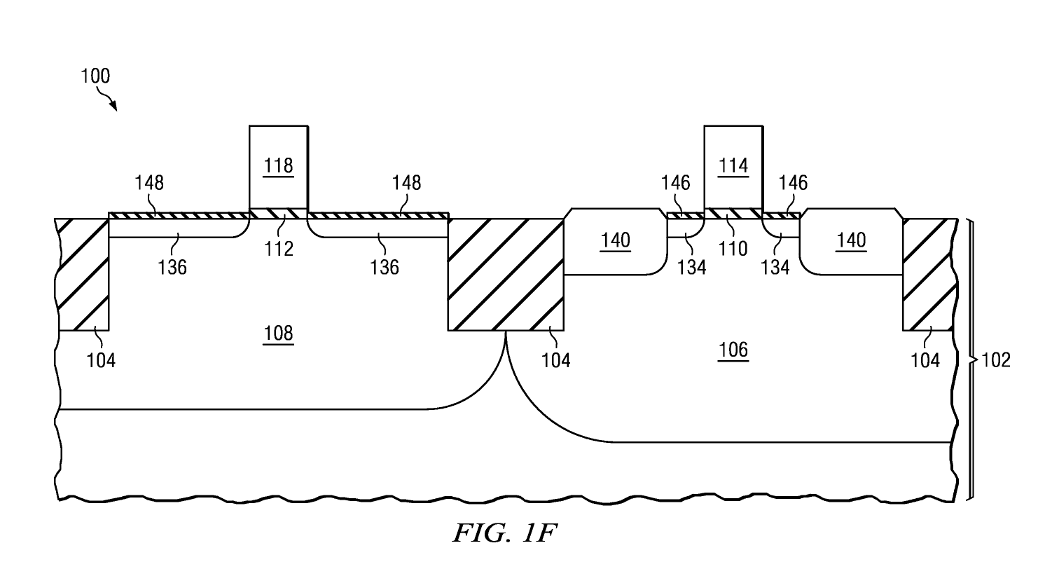

FIGS. 1A-1F show an example embodiment illustrating formation of a chemical oxide layer on an IC, anneal of the chemical oxide layer to form a densified chemical oxide layer, and subsequent exposure to phosphoric acid during a silicon nitride removal process.

Referring to FIG. 1A, an integrated circuit (IC) semiconductor device 100 has a silicon substrate 102, which may be a single crystal wafer, a silicon-on-insulator (SOI) substrate, a hybrid orientation technology (HOT) wafer which features regions with different crystal orientations, or other silicon substrate appropriate for fabrication of the IC 100. Elements of field oxide 104, such as of silicon dioxide regions between 250 and 600 nanometers thick, are formed at a top surface of the substrate 102 by, e.g., shallow trench isolation (STI) processes in which trenches (e.g., 200 to 500 nanometers deep) are etched into the substrate 102, electrically passivated (e.g., by growing a thermal oxide layer on sidewalls of the trenches), and filled with insulating material (e.g., silicon dioxide formed by a high density plasma (HDP) process or an ozone based thermal chemical vapor deposition (CVD) process, also known as the high aspect ratio process (HARP)). An n-type well 106, commonly called an n-well, is formed in the substrate 102, e.g., by ion implanting n-type dopants (e.g., phosphorus, arsenic, and/or antimony, at doses from 1×10¹¹ to 1×10¹⁴ atoms/cm²) into a region of the substrate defined for fabrication of a p-channel metal oxide semiconductor (PMOS) transistor. A photoresist pattern may be used to block the n-type dopants from implantation into regions opf the substrate defined for n-channel metal oxide semiconductor (NMOS) transistors. The n-well 106, e.g., extends from the top surface of the substrate 102 to a depth of 50 to 500 nanometers below the bottom surface of the field oxide elements 104. The ion implantation process to form the n-well 106 may include additional steps to implant additional n-type dopants at shallower depths for purposes of improving PMOS transistor performance, such as threshold adjustment, leakage current reduction and suppression of parasitic bipolar operation. A sheet resistivity of the n-well 106 may, e.g., be between 100 and 1000 ohms/square.

A p-type well 108, commonly called a p-well, is also formed in the substrate 102 by ion implanting p-type dopants (e.g., boron, gallium and/or indium, at doses from 1×10¹¹ to 1×10¹⁴ atoms/cm²) into a region defined for an NMOS transistor. A p-well photoresist pattern may be used to block the p-type dopants from regions defined for PMOS transistors. The p-well 108 extends from a top surface of the substrate 102 to a depth, e.g., 50 to 500 nanometers below a bottom surface of the field oxide elements 104. The ion implantation process to form the p-well 108 may include additional steps to implant additional p-type dopants at shallower depths for purposes of improving NMOS transistor performance, such as threshold adjustment, leakage current reduction and suppression of parasitic bipolar operation.

A PMOS gate dielectric layer 110 (e.g., silicon dioxide, nitrogen doped silicon dioxide, silicon oxynitride, hafnium oxide, layers of silicon dioxide and silicon nitride, or other insulating material, between 1 and 4 nanometers thick) is formed on a top surface of the n-well 106. Similarly, an NMOS gate dielectric layer 112 (e.g., silicon dioxide, nitrogen doped silicon dioxide, silicon oxynitride, hafnium oxide, layers of silicon dioxide and silicon nitride, or other insulating material, between 1 and 4 nanometers thick) is formed on a top surface of the p-well 108. A portion or all of the NMOS gate dielectric layer 112 may be formed concurrently with the PMOS gate dielectric layer 110. A PMOS gate 114 of polysilicon (i.e., polycrystalline silicon) is formed above the PMOS gate dielectric layer 110, and a PMOS gate hardmask 116 of silicon nitride is formed above the PMOS gate 114. Similarly, an NMOS gate 118 of polysilicon is formed over the NMOS gate dielectric layer 112, and an NMOS gate hardmask 120 of silicon nitride is formed over the NMOS gate 118, e.g., concurrently with the PMOS gate 114 and PMOS gate hardmask 116, respectively. The PMOS gate 114, NMOS gate 118, PMOS gate hardmask 116 and NMOS gate hardmask 120 may, e.g., be formed by a process sequence of depositing a layer of polysilicon gate material between 40 and 100 nanometers thick on a top surface of the PMOS gate dielectric layer 110 and a top surface of the NMOS gate dielectric layer 112, depositing a layer of silicon nitride hardmask between 10 and 50 nanometers thick on a top surface of the polysilicon gate material layer, defining area for the PMOS gate 114 and NMOS gate 118 by forming a photoresist pattern using photolithography, removing silicon nitride hardmask material outside the gate area by plasma etching, and removing unwanted polysilicon using etching.

Still referring to FIG. 1A, a polysilicon thermal oxidation process is performed on the IC 100 which grows a layer of thermal silicon dioxide on exposed silicon and polysilicon surfaces and oxidizes exposed silicon nitride on the IC 100, thus forming PMOS active area oxide layers 126 on a top surface of the n-well 106, NMOS active area oxide layers 128 on a top surface of the p-well 108, a layer of PMOS silicon oxynitride 130 on a top surface of the PMOS gate hardmask 116, and a layer of NMOS silicon oxynitride 132 on a top surface of the NMOS gate hardmask 120. One or more conformal layers of silicone nitride and/or silicon dioxide may be formed on lateral surfaces of the PMOS gate 114 and NMOS gate 118 to form PMOS offset spacers 122 and NMOS offset spacers 124, respectively. The PMOS offset spacers 122 may have a different composition and thickness than the NMOS offset spacers 124.

With further reference to FIG. 1A, p-type lightly doped drain (PLDD) regions 134 are formed in top regions of the n-well 106 adjacent to the PMOS offset spacers 122, e.g., by ion implanting p-type dopants (e.g., boron, such as in the form BF₂, and possibly gallium or indium, at a total dose between 1×10¹⁴ and 1×10¹⁵ atoms/cm²) into areas defined for the PLDD regions 134. A photoresist pattern may be used to block the p-type dopants from areas outside the PLDD regions 134. The PLDD regions 134 may, e.g., extend from the top surface of the n-well 106 to a depth of between 10 and 50 nanometers. N-type lightly doped drain (NLDD) regions 136 are formed in the top region of the p-well 108 adjacent to the NMOS offset spacers 124 by ion implanting n-type dopants (e.g., phosphorus and/or arsenic, and/or possibly antimony, at a total dose between 3×10¹⁴ and 3×10¹⁵ atoms/cm²) into areas defined for the NLDD regions 136. A photoresist pattern may be used to block the n-type dopants from areas outside the NLDD regions 136. The NLDD regions 136 may extend from the top surface of the p-well 108 to, e.g., a depth of between 10 and 50 nanometers. The order of formation of the PLDD regions 134 and the NLDD regions 136 may be varied.

A silicon-germanium (Si—Ge) hardmask layer 138 of silicon nitride (e.g., of between 10 and 100 nanometers thickness) is formed on an existing top surface of the IC 100. Si—Ge hardmask material is removed in areas for PMOS Si—Ge source and drain regions adjacent to the PLDD regions 134 by forming a photoresist pattern on a top surface of the Si—Ge hardmask layer to expose silicon nitride in the areas for PMOS Si—Ge source and drain regions, and removing Si—Ge hardmask material using silicon nitride etching methods. Silicon substrate material is removed from the areas for PMOS Si—Ge source and drain regions using silicon etching methods. Si—Ge epitaxial material is grown in the vacated areas to form PMOS Si—Ge source and drain regions 140.

FIG. 1B depicts the IC 100 after a Si—Ge hardmask etch process which removes the silicon-germanium (Si—Ge) hardmask layer shown in FIG. 1A. The Si—Ge hardmask etch process is, e.g., performed by exposing the IC 100 to phosphoric acid between 120° C. and 200° C. Exposed silicon nitride is removed by the Si—Ge hardmask etch process, while silicon dioxide and silicon oxynitride remains substantially unetched by the phosphoric acid. Thus, the PMOS gate hardmask 116 and NMOS gate hardmask 120 are protected by the layer of PMOS silicon oxynitride 130 on the top surface of the PMOS gate hardmask 116 and the layer of NMOS silicon oxynitride 132 on the top surface of the NMOS gate hardmask 120, respectively, from the phosphoric acid. Similarly, the top surfaces of the n-well 106 and the p-well 108 are protected by the PMOS active area oxide layers 126 and the NMOS active area oxide layers 128, respectively.

FIG. 1C depicts the IC 100 at a subsequent stage of fabrication. The PMOS gate hardmask 116 and NMOS gate hardmask 120 are removed in order to form metal silicide on the PMOS gate 114 and NMOS gate 118 during later process steps. A wet etch of the PMOS gate hardmask 116 and NMOS gate hardmask 120 are preferred to avoid overetch damage to the IC from a plasma etch process. Use of a wet etch to remove the PMOS gate hardmask 116 and NMOS gate hardmask 120, for example hot phosphoric acid as described in reference to FIG. 1B, is preceded by removal of the layer of PMOS silicon oxynitride 130 and the layer of NMOS silicon oxynitride 132, in what is commonly known as a deglaze process. FIG. 1C depicts the IC 100 after a deglaze process, e.g., performed by exposing the IC 100 to a dilute or buffered hydrofluoric acid solution. The PMOS silicon oxynitride layer on the PMOS gate hardmask 116 and the NMOS silicon oxynitride on the NMOS gate hardmask 120 are removed by the deglaze process. During the deglaze process, the PMOS active area oxide layers and the NMOS active area oxide layers are undesirably removed.

FIG. 1D depicts the IC 100 after formation of a chemical oxide on exposed silicon surfaces of the IC 100. The chemical oxide formation process is performed using methods which may, e.g., include exposing the IC 100 to an aqueous mixture of sulfuric acid and hydrogen peroxide (commonly known as SPM), or exposing the IC 100 to a mixture of ammonium hydroxide and hydrogen peroxide, or exposing the IC 100 to an oxygen containing plasma (formed, e.g., by 10 to 100 torr of oxygen gas ionized by 50 to 300 watts of RF power), so as to form PMOS active area chemical oxide layers 142 on the top surface of the n-well 106 adjacent to the PMOS gate 114 and NMOS active area chemical oxide layers 144 on the top surface of the p-well 108 adjacent to the NMOS gate 118. The PMOS active area chemical oxide layers 142 and NMOS active area chemical oxide layers 144 are, e.g., 1 to 1.5 nanometers thick. Growth of chemical oxide layers is self-limiting, in that extended exposure to the oxidizing chemicals or oxygen containing plasma after a thickness of, e.g., between 1 and 1.5 nanometers is attained, does not grow significantly more chemical oxide. The PMOS active area chemical oxide layers 142 and NMOS active area chemical oxide layers 144 may be formed by other processes.

FIG. 1E depicts the IC 100 after a chemical oxide anneal process which serves to densify the PMOS active area chemical oxide layers and NMOS active area chemical oxide layers to form PMOS active area densified chemical oxide layers 146 and NMOS active area densified chemical oxide layers 148. The chemical oxide anneal process may be performed in a non-oxidizing ambient, such as nitrogen gas or argon gas, and preferably has a thermal profile which results in an etch rate of the densified chemical oxide layers 146, 148 in hot phosphoric acid of less than one percent an etch rate of silicon nitride, while resulting in less than 3 nanometers root-mean-square (rms) diffusion of dopants in the PLDD regions 134 and NLDD regions 136. For example, an anneal operation between 940° C. and 960° C. for 4 to 5 seconds in an N₂ ambient produces the desired etch rate and rms diffusion limitation. In an alternate embodiment, the chemical oxide anneal process may, e.g., be carried out between 840° C. and 860° C. for 10 to 40 seconds in an N₂ ambient. In a further embodiment, the chemical oxide anneal process may be carried out, e.g., between 1040° C. and 1060° C. for 1 to 2 seconds in an N₂ ambient. In a preferred embodiment, the chemical oxide anneal process is performed in rapid thermal processor (RTP) equipment. In another embodiment, laser scanning anneal equipment may be used. These same thermal profile and ambient conditions may be met using other equipment for the chemical oxide anneal process.

FIG. 1F depicts the IC after a gate hardmask removal etch process, during which the IC 100 is exposed to phosphoric acid at a concentration, e.g., of greater than 80 percent at a temperature between 120° C. and 200° C. The PMOS gate hardmask and the NMOS gate hardmask are removed by the gate hardmask removal etch process. The PMOS active area densified chemical oxide layers 146 and NMOS active area densified chemical oxide layers 148 are not removed during the gate hardmask removal etch process, and the underlying PLDD regions (PLDD regions 134 and NLDD regions 136) are desirably undamaged by the phosphoric acid.

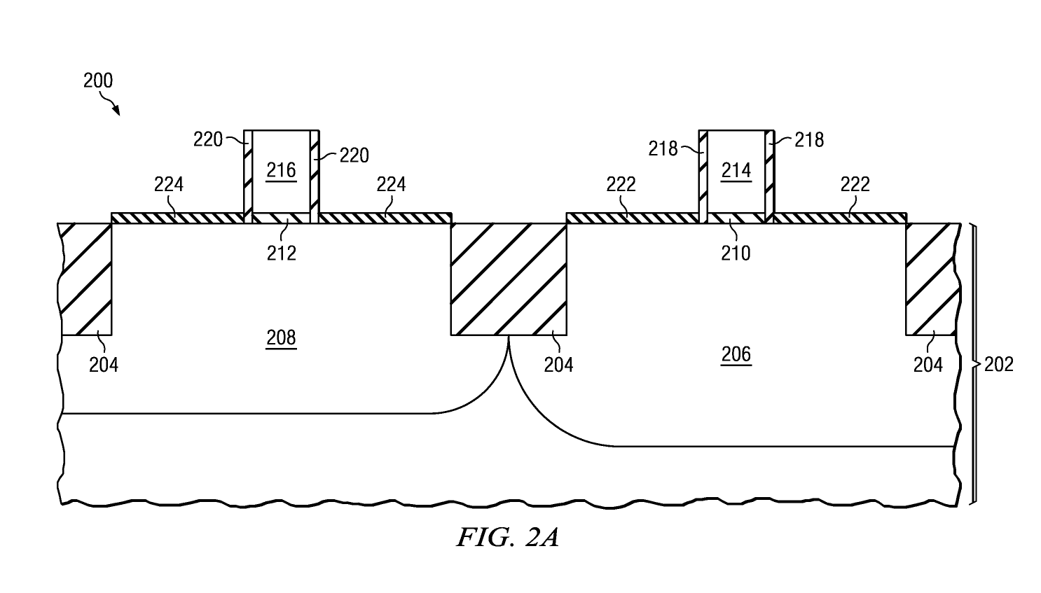

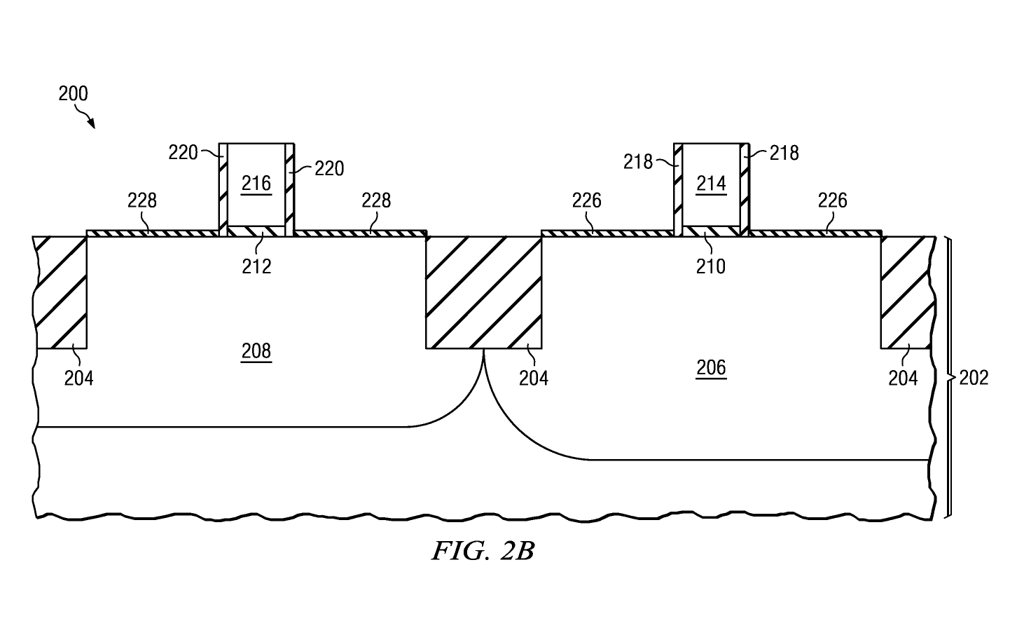

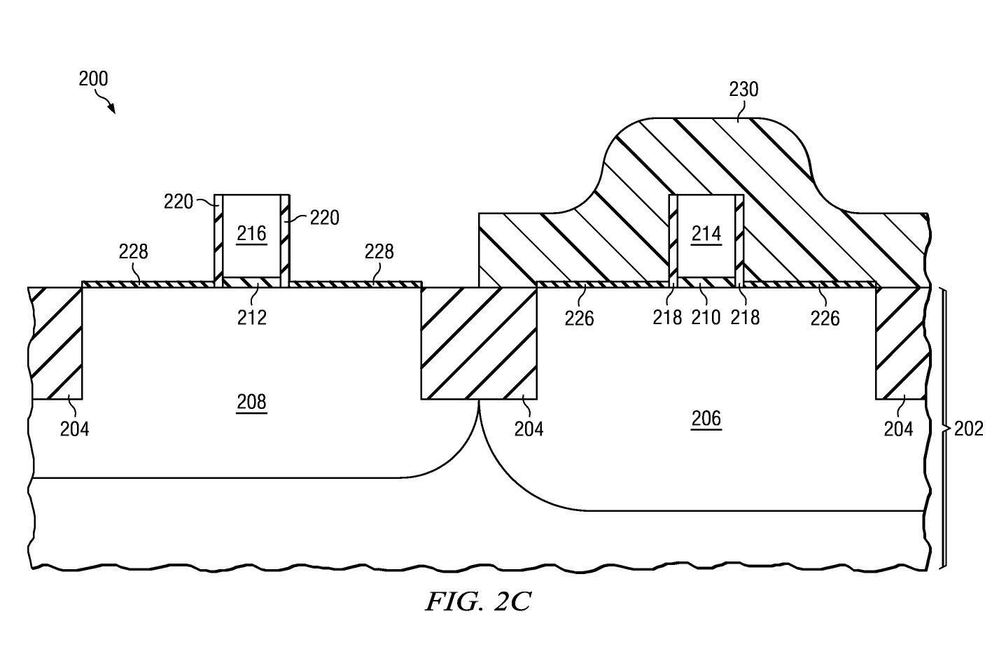

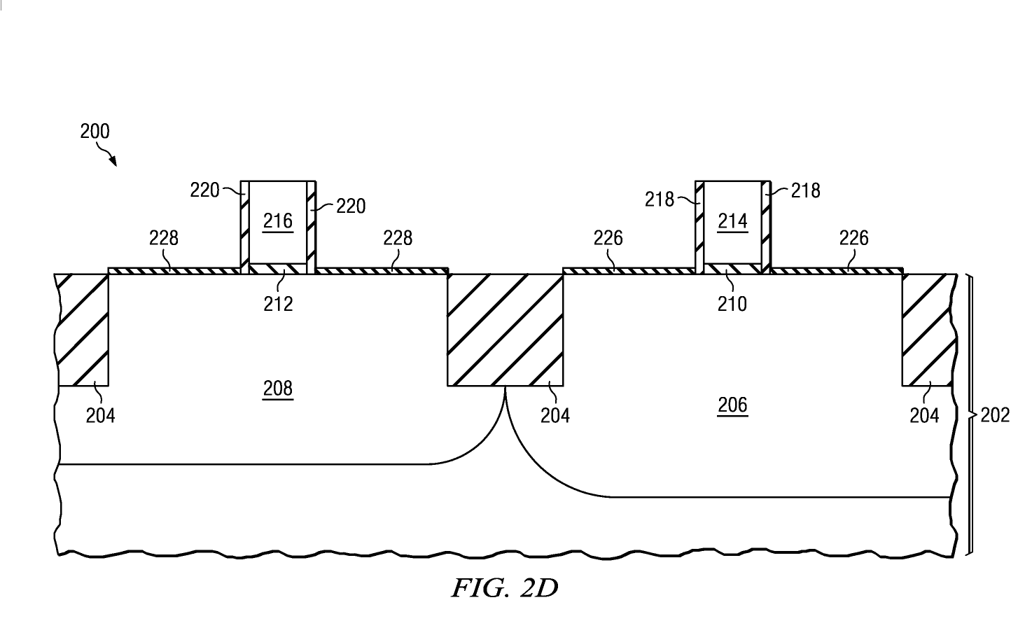

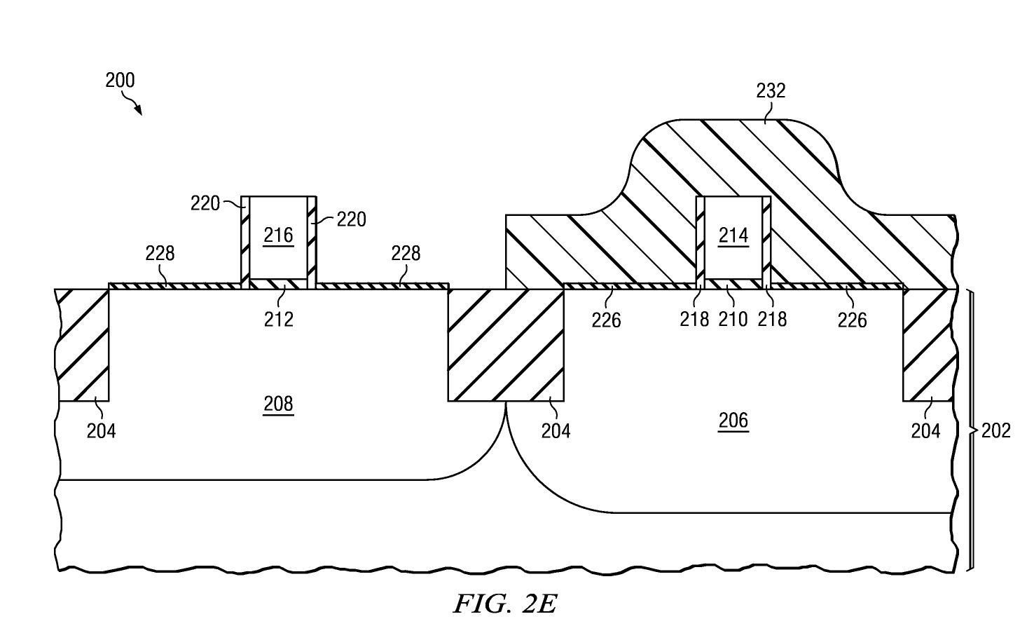

FIGS. 2A-2E show another example embodiment illustrating formation of a chemical oxide layer on an IC, anneal of the chemical oxide layer, and subsequent exposure to alkaline photoresist developer during a photolithographic rework process.

Referring to FIG. 2A, an integrated circuit (IC) 200 is formed on a silicon substrate 202. Similarly to the IC 100 described above with reference to FIG. 1A, IC 200 includes elements of field oxide 204 formed at a top surface of the substrate 202; an n-well 206 formed in the substrate 202 in an area defined for a PMOS transistor; a p-well 208 formed in the substrate 202 in an area defined for an NMOS transistor; and a PMOS gate dielectric layer 210 formed on a top surface of the n-well 206. Also, similarly to IC 100, IC 200 includes an NMOS gate dielectric layer 212 formed on a top surface of the p-well 208; a PMOS gate 214 of polysilicon (e.g., 40 to 100 nanometers thick) formed on a top surface of the PMOS gate dielectric layer 210; and an NMOS gate 216 of polysilicon formed on a top surface of the NMOS gate dielectric layer 212. One or more conformal layers of silicone nitride and/or silicon dioxide may be formed on lateral surfaces of the PMOS gate 214 and NMOS gate 216 to form PMOS offset spacers 218 and NMOS offset spacers 220, respectively. The PMOS offset spacers 218 may have a different composition and thickness than the NMOS offset spacers 220.

With further reference to FIG. 2A, PMOS active area chemical oxide layers 222 are formed on the top surface of the n-well 206 adjacent to the PMOS offset spacers 218 by removing any thermally grown or deposited oxide layers on the top surface of the n-well 206 and exposing the IC 200 to oxidizing chemicals such as SPM, or a mixture of ammonium hydroxide and hydrogen peroxide, or exposing the IC 200 to an oxygen containing plasma as described in reference to FIG. 1D. Similarly, NMOS active area chemical oxide layers 224 are formed on the top surface of the p-well 208 adjacent to the NMOS offset spacers 220, e.g., concurrently with the PMOS active area chemical oxide layers 222. The PMOS active area chemical oxide layers 222 and NMOS active area chemical oxide layers 224 may be, e.g., 1 to 1.5 nanometers thick. As previously described, the growth of chemical oxide layers is self-limiting in that extended exposure to the oxidizing chemicals or oxygen containing plasma, after a given thickness (e.g., between 1 and 1.5 nanometers) is attained, does not grow significantly more chemical oxide. The PMOS active area chemical oxide layers 222 and NMOS active area chemical oxide layers 224 may be grown by other processes.

FIG. 2B depicts the IC 100 after a chemical oxide anneal process is performed to densify the PMOS active area chemical oxide layers and NMOS active area chemical oxide layers to form PMOS active area densified chemical oxide layers 226 and NMOS active area densified chemical oxide layers 228. The chemical oxide anneal process may be performed in a non-oxidizing ambient, such as nitrogen gas or argon gas, and preferably has a thermal profile which results in an etch rate of the densified chemical oxide layers 226, 228 in alkaline photoresist developer less than one-tenth Angstrom per minute, while resulting in less than 3 nanometers root-mean-square (rms) diffusion of dopants in the n-well 206 and p-well 208. For example, an anneal operation between 940° C. and 960° C for 4 to 5 seconds in an N₂ ambient produces the desired etch rate and rms diffusion. In an alternate embodiment, the chemical oxide anneal process may be carried out between 840° C. and 860° C. for 10 to 40 seconds in an N₂ ambient. In a further embodiment, the chemical oxide anneal process may be carried out between 1040° C. and 1060° C. for 1 to 2 seconds in an N₂ ambient. In a preferred embodiment, the chemical oxide anneal process is performed in rapid thermal processor (RTP) equipment. In another embodiment, laser scanning anneal equipment may be used. Other equipment may be used to achieve the same thermal profile and ambient conditions, if desired.

FIG. 2C depicts the IC 200 after formation of a first NLDD photoresist pattern 230 on a top surface of the n-well 206. During formation of the first NLDD photoresist pattern 230, the NMOS active area densified chemical oxide layers 228 are exposed to alkaline photoresist developer, e.g., between 10 and 300 seconds. Less than 0.5 Angstroms of the NMOS active area densified chemical oxide layers 228 is removed by the alkaline photoresist developer during the first pattern develop step, as a result of the chemical oxide anneal process. Chemical oxide layers which are not densified may be expected to lose several Angstroms during a typical photoresist patterning step.

FIG. 2D depicts the IC 200 after the first NLDD photoresist pattern is removed during a photoresist rework process, which involves removal of a photoresist pattern due to misalignment or other reason, and formation of a second photoresist pattern. During the removal of the first NLDD photoresist pattern, the NMOS active area densified chemical oxide layers 228 are exposed to alkaline photoresist developer, e.g., between 30 and 300 seconds. Less than 0.5 Angstroms of the NMOS active area densified chemical oxide layers 228 is removed by the alkaline photoresist developer during the pattern removal step as a result of the chemical oxide anneal process. Chemical oxide layers which are not densified may be expected to lose several Angstroms during a typical photoresist pattern removal process.

FIG. 2E depicts the IC 200 after formation of a second NLDD photoresist pattern 232 on a top surface of the n-well 206. During formation of the second NLDD photoresist pattern 230, the NMOS active area densified chemical oxide layers 228 are exposed to alkaline photoresist developer, e.g., between 10 and 300 seconds. Less than 0.5 Angstroms of the NMOS active area densified chemical oxide layers 228 is removed by the alkaline photoresist developer during the second pattern develop step as a result of the chemical oxide anneal process. Chemical oxide layers which are not densified may be expected to be completely removed after a photoresist rework process sequence.

Performing the chemical oxide anneal process as described in reference to FIGS. 2A-2E is advantageous because the top surface of the n-well is protected during the photolithographic rework process sequence and subsequent fabrication processes by the densified chemical oxide.

Those familiar with integrated circuit fabrication processes will recognize that the advantages of annealing the chemical oxide layers will accrue during a photolithographic rework sequence of a PLDD photoresist pattern similarly to the photolithographic rework sequence of the NLDD photoresist pattern described in reference to FIGS. 2A-2E.

Those skilled in the art to which the invention relates will appreciate that many other embodiments and modifications are possible within the scope of the claimed invention.

What is claimed is:

1. A method of forming a semiconductor device, comprising:
forming a chemical oxide layer on a surface of a silicon region of a substrate;
performing an anneal in a non-oxidizing ambient to densify the chemical oxide;
whereby a densified chemical oxide layer is provided that has an etch rate in phosphoric acid equivalent to the etch rate of thermally grown silicon dioxide.

2. The method of claim 1, wherein the anneal comprises heating the chemical oxide layer at 940° C. to 960° C. for 4 to 5 seconds.

3. The method of claim 1, wherein the anneal comprises heating said chemical oxide layer at 1040° C. to 1060° C. for 1 to 2 seconds.

4. The method of claim 1, wherein the non-oxidizing ambient consists substantially of N₂ gas.

5. The method of claim 1, wherein the non-oxidizing ambient consists substantially of argon gas.

6. The method of claim 1, wherein the anneal is performed in rapid thermal processor equipment.

7. The method of claim 1, wherein the silicon region is an n-type doped region having a dopant concentration above 10¹⁹ cm⁻³.

8. A method of forming a semiconductor device, comprising the steps of:
forming a chemical oxide layer on a surface of a MOS transistor active region of a substrate; and
densifying the chemical oxide layer by a process including annealing the chemical oxide layer in a non-oxidizing ambient;
whereby a densified chemical oxide layer is provided that has an etch rate in phosphoric acid equivalent to the etch rate of thermally grown silicon dioxide.

9. The method of claim 8, wherein the annealing comprises heating the chemical oxide layer at 940° C. to 960° C. for 4 to 5 seconds.

10. The method of claim 8, wherein the annealing comprises heating the chemical oxide layer at 1040° C. to 1060° C. for 1 to 2 seconds.

11. The method of claim 8, wherein the non-oxidizing ambient consists substantially of N₂ gas.

12. The method of claim 8, wherein the annealing comprises positioning the substrate in rapid thermal processor equipment.

13. The method of claim 8, wherein the active region is an n-type doped region with a dopant concentration above 10¹⁹ cm⁻³.

14. An semiconductor device, comprising:
a MOS transistor formed in an active region of a silicon containing substrate;
a chemical oxide layer formed on a surface of the active region; the chemical oxide layer having been densified by annealing in a non-oxidizing ambient and having an etch rate in phosphoric acid that is equivalent to an etch rate of thermally grown silicon dioxide.

15. The integrated circuit of claim 14, wherein the active region is an n-type doped region with a dopant concentration above 10¹⁹ cm⁻³.
